(19) United States
(12) Patent Application Publication
(10) Pub. No.: US 2013/0121356 A1
(43) Pub. Date: May 16, 2013

(54) DRIVER CIRCUIT AND OPTICAL TRANSMITTER

(71) Applicant: FUJITSU LIMITED, Kawasaki-shi (JP)

(72) Inventor: Mariko Sugawara, Zama (JP)

(73) Assignee: FUJITSU LIMITED, Kawasaki-shi (JP)

(21) Appl. No.: 13/625,981

(22) Filed: Sep. 25, 2012

(30) Foreign Application Priority Data
Nov. 16, 2011 (JP) 2011-251101

(51) Int. Cl. H05B 37/02; H01S 5/183

(52) U.S. Cl. 372/38.02; 315/172

(57) ABSTRACT

An apparatus includes a first input transistor to include a base receiving a drive signal for an object to be driven, a first current source connected to an emitter side of the first input transistor and configured to control a modulation amplitude of a signal flowing to a collector of the first input transistor, a second current source connected to a collector side of the first input transistor and configured to control a biased current of a signal flowing to the collector, a first inductor configured to dispose between the collector and the second current source, and an output element connected between the second current source and the first inductor and configured to output, to the object, a current signal of which the modulation amplitude is controlled by the first current source and the biased current is controlled by the second current source.

### CROSS-REFERENCE TO RELATED APPLICATION

This application is based upon and claims the benefit of priority of the prior Japanese Patent Application No. 2011-251101, filed on Nov. 16, 2011, the entire contents of which are incorporated herein by reference.

### FIELD

The embodiments discussed herein are related to a driver circuit and an optical transmitter.

### BACKGROUND

With an increase in the transmission speed and transmission volume through the application of optical interconnect, the use of light in, for example, close range and middle range communication has been considered. Some known light signal sources for optical transmission include a vertical cavity surface emitting laser (VCSEL) device, which is small and enables modulation by a direct current at low power consumption. A driver circuit that modulates the VCSEL by a direct current includes, for example, a modulated current source that controls the modulated current amplitude and a biased current source that directly supplies a current having an adjusted direct current level to an output terminal.

A current mode logic (CML) in which a load resistance, instead of a current source, is connected to the output terminal is known (for example, refer to Sudip Shekhar, Jeffrey S. Walling, David J. Allstot, “Bandwidth Extension Techniques for CMOS Amplifiers”, IEEE JOURNAL OF SOLID-STATE CIRCUITS VOL. 41 No. 11 November 2006, pp. 2424-2439). A series inductor is connected to the CML to divide the capacitance value and improve the rising edge characteristics (through rate) of the output waveform.

Such a known driver circuit including an output terminal to which a biased current source is connected has a problem in that the biased current source contains equivalent resistance and capacitance, causing reduction in the frequency band due to the capacitance of the biased current source.

### SUMMARY

According to an aspect of the embodiments, an apparatus includes a first input transistor to include a base receiving a drive signal for an object to be driven, a first current source connected to an emitter side of the first input transistor and configured to control a modulation amplitude of a signal flowing to a collector of the first input transistor, a second current source connected to a collector side of the first input transistor and configured to control a biased current of a signal flowing to the collector, a first inductor configured to dispose between the collector and the second current source, and an output element connected between the second current source and the first inductor and configured to output, to the object, a current signal of which the modulation amplitude is controlled by the first current source and the biased current is controlled by the second current source.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 illustrates an exemplary configuration of a driver circuit according to an embodiment.

FIG. 2A illustrates an exemplary drive signal output from a driver circuit.

FIG. 2B illustrates an exemplary small-signal characteristic of a driver circuit.

FIG. 3A illustrates, for reference, a driver circuit including an inductor disposed at a first position.

FIG. 3B illustrates, for reference, a driver circuit including an inductor disposed at a second position.

FIG. 3C illustrates, for reference, a configuration example 1 of a CML (Current Mode Logic).

FIG. 3D illustrates, for reference, a configuration example 2 of the CML.

FIG. 3E illustrates, for reference, a configuration example 3 of the CML.

FIG. 4A illustrates an exemplary simulation result of a small-signal characteristic of a driver circuit.

FIG. 4B illustrates, for reference, an exemplary simulation result of a small-signal characteristic in a CML.

FIG. 5A illustrates an equivalent circuit of the driver circuit illustrated in FIG. 1.

FIG. 5B illustrates, for reference, an equivalent circuit of the driver circuit in FIG. 3A.

FIG. 5C illustrates, for reference, an equivalent circuit of the driver circuit in FIG. 3B.

FIG. 6A illustrates an exemplary calculation result of an impedance of the equivalent circuit in FIG. 5A.

FIG. 6B illustrates, for reference, an exemplary calculation result of an impedance of the equivalent circuit in FIG. 5B.

FIG. 6C illustrates, for reference, an exemplary calculation result of an impedance of the equivalent circuit in FIG. 5C.

FIG. 7 illustrates a modification 1 of the driver circuit illustrated in FIG. 1.

FIG. 8 illustrates a modification 2 of the driver circuit illustrated in FIG. 1.

FIG. 9 illustrates a modification 3 of the driver circuit illustrated in FIG. 1. and

FIG. 10 illustrates a modification 4 of the driver circuit illustrated in FIG. 1.

### DESCRIPTION OF EMBODIMENT

A driver circuit and an optical transmitter according to an embodiment will now be described in detail with reference to the accompanying drawings.

Configuration of Driver Circuit According to Embodiment

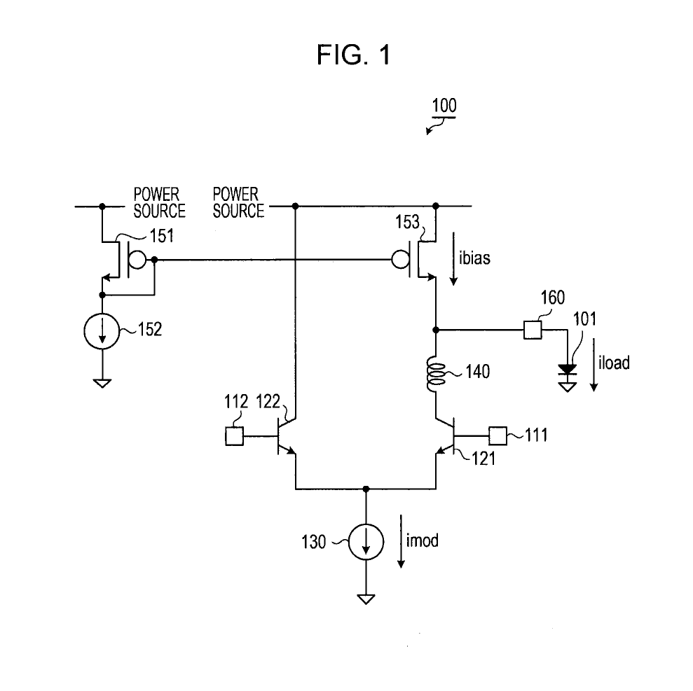

FIG. 1 illustrates an exemplary configuration of a driver circuit according to the embodiment. The driver circuit 100, which is illustrated in FIG. 1, amplifies a drive signal for driving a light-emitting element 101. The light-emitting element 101 emits light directly modulated (intensity-modulated) by an input current signal. The light-emitting element 101 is, for example, a VCSEL device.

The driver circuit 100, which is illustrated in FIG. 1, performs anode driving of the light-emitting element 101. Specifically, the driver circuit 100 includes input elements 111 and 112, input transistors 121 and 122, a modulated current source 130, an inductor 140, a transistor 151, a current source 152, a transistor 153, and an output element 160. In this specification, the input elements and the output element are, for example, terminals, pads, and/or wires that connect with other circuits.

The drive signal input to the driver circuit 100 is, for example, a differential signal containing a positive phase signal component and a reversed phase signal component. The reversed phase signal is a signal obtained by reversing the positive phase signal. The input elements 111 and 112 are a differential pair of input elements to which a differential drive signal is input. Specifically, the input element 111 receives the positive phase signal component of the drive signal. The signal component input to the input element 111 is output to the base of the input transistor 121. The input element 112 receives the reversed phase signal component of the drive signal. The signal component input to the input element 112 is output to the base of the input transistor 122.

The input transistors 121 and 122 are, for example, heterojunction bipolar transistors (HBT) or complementary metal oxide semiconductors (CMOS). A case in which the input transistors 121 and 122 are HBTs will be described below.

The base of the input transistor 121 is connected to the input element 111. The collector of the input transistor 121 is connected to the inductor 140. The emitter of the input transistor 121 is connected to the modulated current source 130. The base of the input transistor 122 is connected to the input element 112. The collector of the input transistor 122 is connected to a power source. The emitter of the input transistor 122 is connected to the modulated current source 130.

The modulated current source 130 receives currents from the input transistors 121 and 122 and controls modulation amplitude imod of the drive signal. One of the terminals of the modulated current source 130 is connected to the input transistors 121 and 122, and the other terminal is grounded.

The inductor 140 is a series inductor disposed between the collector of the input transistor 121 and the transistor 153. Specifically, one of the terminals of the inductor 140 is connected to the input transistor 121, and the other terminal is connected to the transistor 153 and the output element 160.

The transistor 151 and the current source 152 are current sources. Specifically, the drain of the transistor 151 is connected to the power source. The gate of the transistor 151 is connected to the source of the transistor 151 and the transistor 153. The source of the transistor 151 is connected to the current source 152 and the transistor 153. The transistor 151 is a pMOS. One of the terminals of the current source 152 is connected to the transistor 151, and the other terminal is grounded.

The transistor 153 is a biased current source that controls a biased current ibias (direct current level) of the drive signal. Specifically, the source of the transistor 153 is connected to the inductor 140 and the output element 160. The drain of the transistor 153 is connected to the power source. The gate of the transistor 153 is connected to the transistor 151. The transistor 153 is a pMOS.

The output element 160 outputs, to the light-emitting element 101, a drive signal whose modulation amplitude is controlled by the modulated current source 130, and whose biased current is controlled by the transistor 153 (biased current source). Specifically, the output element 160 is connected between the transistor 153 and the inductor 140. The output element 160 is connected to the light-emitting element 101, which is driven by the driver circuit 100. The output element 160 outputs a drive signal to the light-emitting element 101. The current of the drive signal output from the output element 160 and input to the light-emitting element 101 is represented by the reference characters “iload.”

As described above, the inductor 140 is disposed between the collector of the input transistor 121 and the output element 160, in parallel with the transistor 153 (biased current source). Accordingly, a wider frequency band may be obtained by inductor peaking (details will be described below). The frequency band of a light signal transmitted by an optical transmitter is widened by using the optical transmitter including the driver circuit 100 and the light-emitting element 101.

In the case illustrated in FIG. 1, the drive signal input to the driver circuit 100 is a differential signal. Instead, the drive signal input to the driver circuit 100 may be a single-ended signal. In such a case, the drive signal is input to the input element 111. In this case, the input element 112 and the input transistor 122 may be omitted, for example.

In the case illustrated in FIG. 1, the input transistors 121 and 122 are HBTs. Instead, the input transistors 121 and 122 may each be a CMOS including a source, a gate, and a drain. In such a case, the above-mentioned emitter, base, and collector corresponding to the source, gate, and drain, respectively.

Drive Signal Output from Driver Circuit

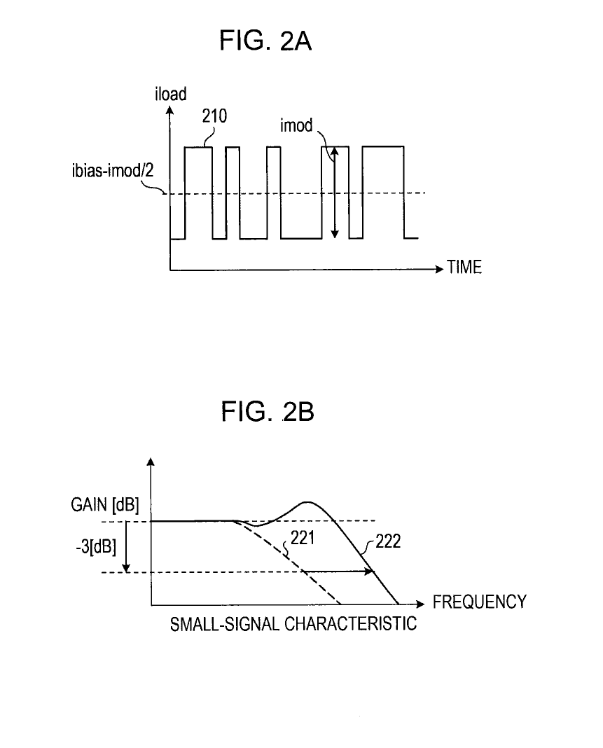

FIG. 2A illustrates an exemplary drive signal output from the driver circuit. In FIG. 2A, the transverse axis represents time, and the vertical axis represents a current iload of the drive signal output from the driver circuit 100 to the light-emitting element 101. A drive signal 210 is output from the driver circuit 100 to the light-emitting element 101.

The amplitude of the drive signal 210 is the modulation amplitude imod controlled by the modulated current source 130. The biased current of the drive signal 210 is represented by “ibias-imode/2” based on the modulation amplitude imod controlled by the modulated current source 130 and the biased current ibias controlled by the transistor 153.

Small-Signal Characteristic of Driver Circuit

FIG. 2B illustrates an exemplary small-signal characteristic of a driver circuit. In FIG. 2B, the transverse axis represents frequency. The vertical axis represents gain (dB) of the drive signal. A small-signal characteristic curve 221 represents, for reference, a small-signal characteristic (frequency characteristic) of the drive signal if the inductor 140 is not mounted in the driver circuit 100. As indicated by the small-signal characteristic curve 221, the gain in the high frequency band is impaired by the parasitic capacitance of the transistor 153 (current source) if the inductor 140 is not provided.

The small-signal characteristic curve 222 represents the small-signal characteristic of the drive signal in the driver circuit 100 including the inductor 140, as illustrated in FIG. 1. As indicated by the small-signal characteristic curve 222, the high frequency band peaks as a result of providing the inductor 140, and the impaired gain in the high frequency band is compensated for.

Driver Circuits Including Inductors Mounted at Different Positions

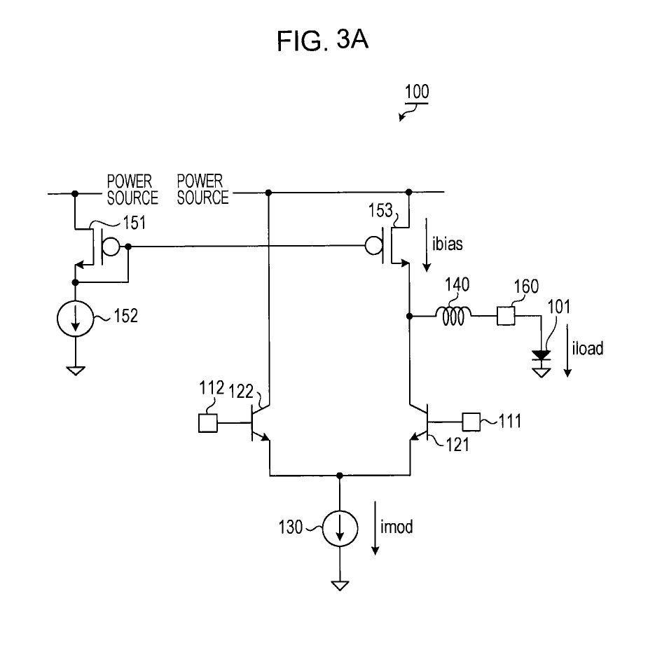

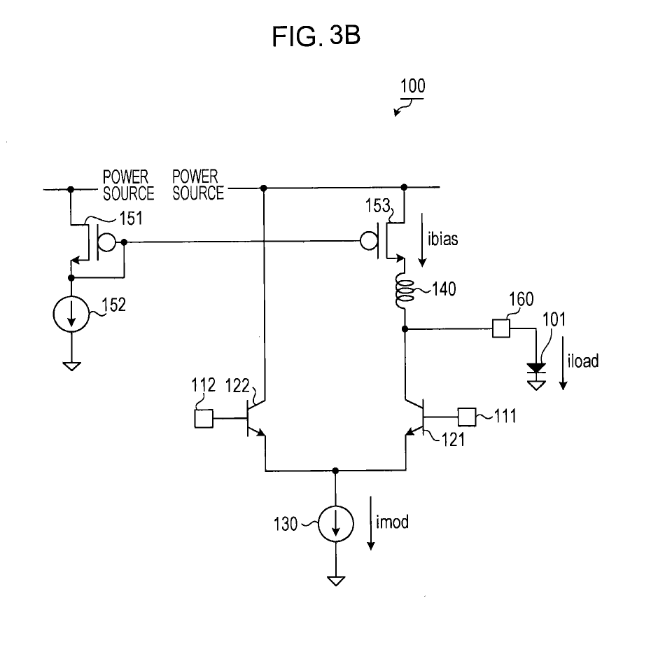

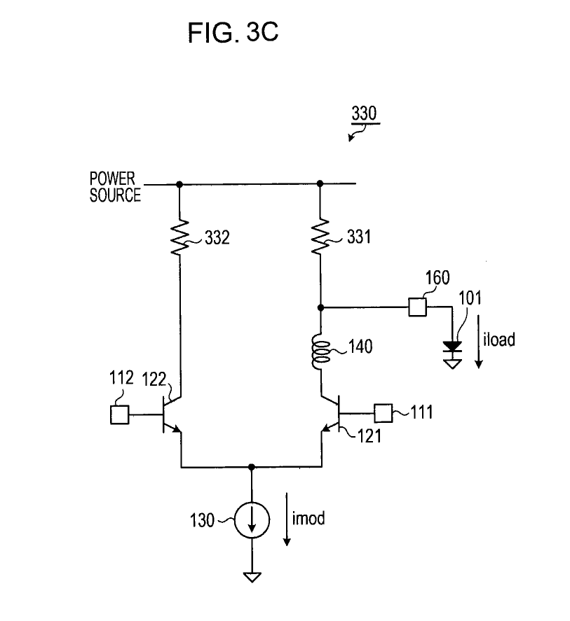

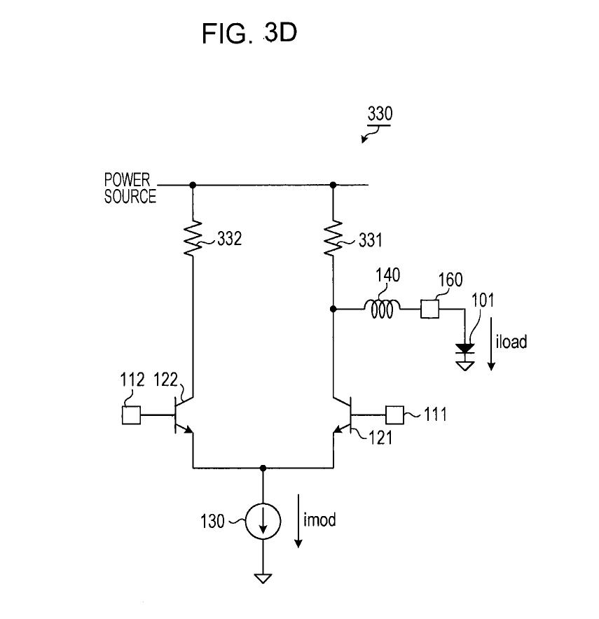

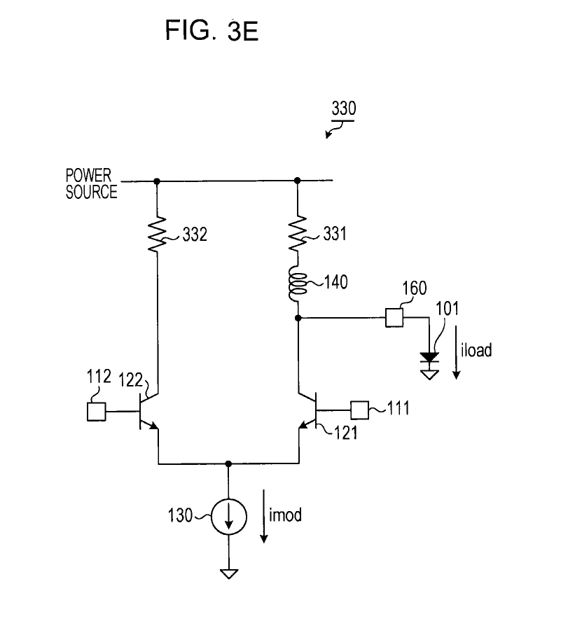

FIG. 3A illustrates, for reference, a driver circuit including an inductor disposed at a first position. In FIG. 3A, the same elements as those illustrated in FIG. 1 will be designated by the same reference numerals, and descriptions thereof will not be repeated. FIG. 3A illustrates, for reference, a configuration in which one of the terminals of the inductor 140 is connected to the transistor 153 and the input transistor 121, and the other terminal is connected to the output element 160 in the driver circuit 100, which is illustrated in FIG. 1. The inductor 140 in the configuration illustrated in FIG. 3A is a series inductor disposed in series between the input transistor 121 and the output element 160.

FIG. 3B illustrates, for reference, a driver circuit including an inductor disposed at a second position. In FIG. 3B, the same elements as those illustrated in FIG. 1 will be designated by the same reference numerals, and descriptions thereof will not be repeated. FIG. 3B illustrates, for reference, a configuration in which one of the terminals of the inductor 140 is connected to the transistor 153, and the other terminal is connected to the input transistor 121 and the output element 160 in the driver circuit 100, which is illustrated in FIG. 1. The inductor 140 in the configuration illustrated in FIG. 3B is a shunt inductor connected in parallel to a path between the input transistor 121 and the output element 160.

Exemplary Configurations of CML (Current Mode Logic)

FIG. 3C illustrates, for reference, a configuration example 1 of the CML. In FIG. 3C, the same elements as those illustrated in FIG. 1 will be designated by the same reference numerals, and descriptions thereof will not be repeated. The CML 330 illustrated in FIG. 3C includes the input elements 111 and 112, the input transistors 121 and 122, the modulated current source 130, the inductor 140, resistors 331 and 332, and the output element 160. One of the terminals of the resistor 331 is connected to the inductor 140 and the output element 160, and the other terminal is connected to a power source. One of the terminals of the resistor 332 is connected to the collector of the input transistor 122, and the other terminal is connected to the power source. In this way, in the CML 330, the output element 160 is connected to a voltage source (power source) and the resistor 331, instead of the current source.

FIG. 3D illustrates, for reference, a configuration example 2 of the CML. In FIG. 3D, the same elements as those illustrated in FIG. 3C will be designated by the same reference numerals and descriptions thereof will not be repeated. The configuration in FIG. 3D is the same as that in FIG. 3C except that one of the terminals of the inductor 140 in the CML 330 is connected to the resistor 331 and the input transistor 121, and the other terminal is connected to the output element 160.

FIG. 3E illustrates, for reference, a configuration example 3 of the CML. In FIG. 3E, the same elements as those illustrated in FIG. 3C will be designated by the same reference numerals, and descriptions thereof will not be repeated. The configuration in FIG. 3E is the same as that in FIG. 3C except that one of the terminals of the inductor 140 in the CML 330 is connected to the resistor 331 and the other terminal is connected to the input transistor 121 and the output element 160.

Simulation Results of Small-Signal Characteristic of Driver Circuit

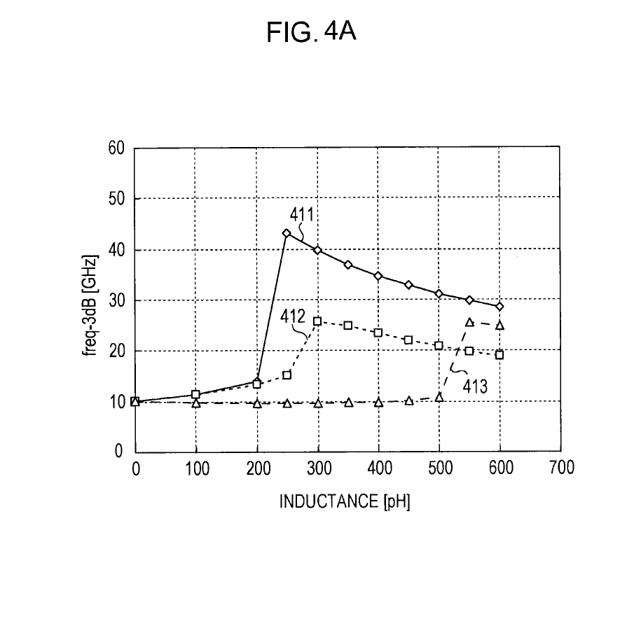

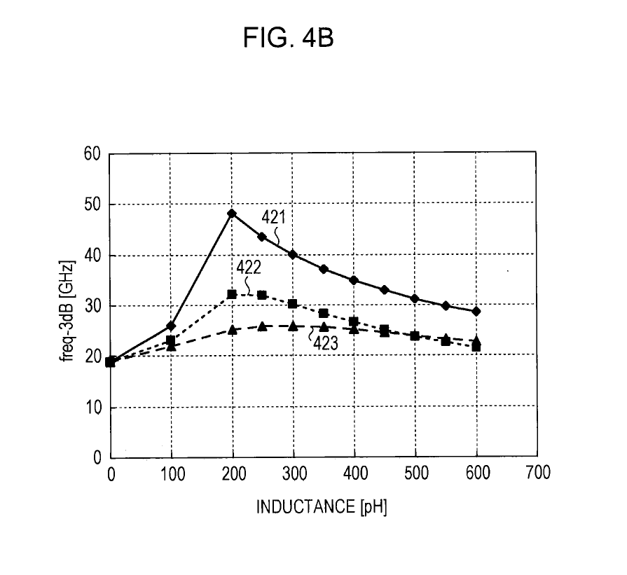

FIG. 4A illustrates exemplary simulation results of the small-signal characteristic of the driver circuit. In FIG. 4A, the transverse axis represents the inductance (pH) of the inductor 140. The zero inductance (pH) point on the transverse axis corresponds to a configuration not including the inductor 140. The vertical axis represents a frequency band (GHz) in which the signal strength is −3 dB (freq-3 dB).

The small-signal characteristic line 411 represents the small-signal characteristic of the driver circuit 100 that is illustrated in FIG. 1. The small-signal characteristic line 412 represents, for reference, the small-signal characteristic of the driver circuit 100 that is illustrated in FIG. 3A. The small-signal characteristic line 413 represents, for reference, the small-signal characteristic of the driver circuit 100 that is illustrated in FIG. 3B.

As represented by the small-signal characteristic lines 411 to 413, the frequency band of a drive signal may be widened by providing the inductor 140 (inductance>0 pH) in the driver circuit 100. Specifically, as represented by the small-signal characteristic line 411, a wide frequency band of 40 GHz or more may be achieved by providing the inductor 140 at the position illustrated in FIG. 1.

As indicated by the point at which the inductance of the small-signal characteristic lines 411 to 413 is zero pH, the frequency band is approximately 10 GHz if the inductor 140 is not provided. Thus, with the driver circuit 100 illustrated in FIG. 1, the frequency band may be widened by three to four times by providing the inductor 140 at the position illustrated in FIG. 1.

Simulation Results of Small-Signal Characteristics of CML

FIG. 4B illustrates, for reference, exemplary simulation results of the small-signal characteristics of the CML. In FIG. 4B, the transverse axis represents the inductance (pH) of the inductor 140 (FIGS. 3C to 3E) provided in the CML 330. The vertical axis represents the frequency band (GHz) in which the signal strength is −3 dB.

The small-signal characteristic lines 421 to 423 are illustrated for reference and represent the small-signal characteristics of the CML 330 illustrated in FIGS. 3C to 3E, respectively. As represented by the small-signal characteristic lines 421 to 423, the frequency band widens only by approximately 2.5 times even when the inductor 140 is disposed in the CML 330 because a current source is not disposed at the output element 160.

Equivalent Circuit of Driver Circuit

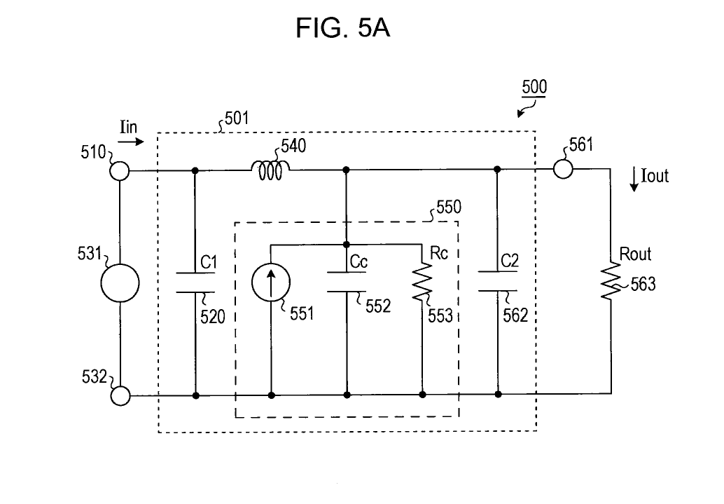

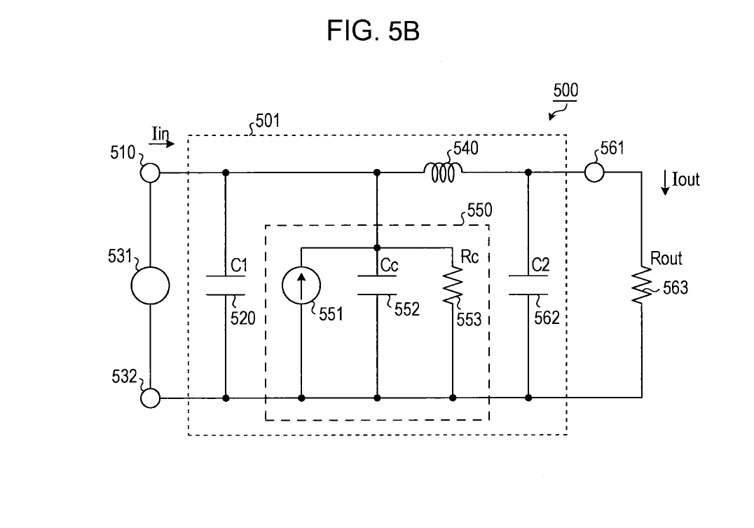

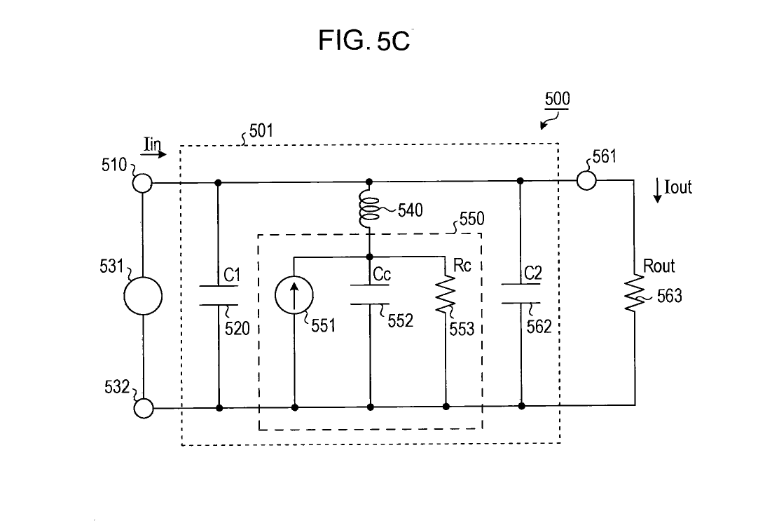

FIG. 5A illustrates an equivalent circuit of the driver circuit illustrated in FIG. 1. An equivalent circuit 500 illustrated in FIG. 5A is an equivalent circuit of the driver circuit 100 illustrated in FIG. 1. As illustrated in FIG. 5A, the equivalent circuit 500 includes an input element 510, a capacitor 520, an AC current source 531, an AVSS 532, an inductor 540, a current-source equivalent circuit 550, an output element 561, a capacitor 562, and a resistor 563.

The input element 510 and the capacitor 520 respectively correspond to the input element 111 and the input transistor 121 in FIG. 1. Iin represents the current of the drive signal from the input element 510. The capacitance C1 of the capacitor 520 is the parasitic capacitance of the input transistor 121. The AC current source 531 and the AVSS 532 correspond to the modulated current source 130 in FIG. 1. The inductor 540 corresponds to the inductor 140 in FIG. 1. The current-source equivalent circuit 550 corresponds to the transistor 153 in FIG. 1.

The current-source equivalent circuit 550 is represented by an ideal current source 551, an ideal capacitor 552, and an ideal resistor 553, all connected in parallel. The capacitance Cc of the capacitor 552 and the resistance Rc of the resistor 553 are the parasitic capacitance and parasitic resistance of the transistor 153.

The output element 561, the capacitor 562, and the resistor 563 correspond to the output element 160 in FIG. 1. lout represents a current of the drive signal from the output element 561. The capacitance C2 of the capacitor 562 is the capacitance of the pad of the output element 160 and the electrostatic protection for semiconductor device (ESD). The resistance Rout of the resistor 563 is the resistance of the output element 160. The current transfer function of a partial circuit 501 may be represented by the following Expression 1:

$$\vert S ( j ω ) \vert = \vert Iout / Iin \vert = \vert \frac{1}{( Rout / Z ( j ω ) ) + 1} \vert \qquad ( 1 )$$

where Z represents the impedance of the partial circuit 501 of the equivalent circuit 500.

The peak illustrated in FIG. 2B occurs at a frequency at which the impedance Z is a maximum value. The peak amount is determined by the maximum value (Zmax) of the impedance Z. A large Zmax significantly increases the gain. Thus, by controlling the frequency corresponding to the peak at a desired value, the frequency band may be widened such that the signal intensity is −3 dB (see FIG. 2B).

FIG. 5B illustrates, for reference, an equivalent circuit of the driver circuit illustrated in FIG. 3A. In FIG. 5B, the same elements as those illustrated in FIG. 5A will be designated by the same reference numerals, and descriptions thereof will not be repeated. The equivalent circuit 500 illustrated in FIG. 5B is an equivalent circuit of the driver circuit 100 in FIG. 3A. As illustrated in FIG. 5B, one of the terminals of the inductor 540 in the equivalent circuit 500 corresponding to the driver circuit 100 in FIG. 3A is connected to the input element 510 and the current-source equivalent circuit 550, and the other terminal is connected to the output element 561.

FIG. 5C illustrates, for reference, an equivalent circuit of the driver circuit illustrated in FIG. 3B. In FIG. 5C, the same elements as those illustrated in FIG. 5A will be designated by the same reference numerals, and descriptions thereof will not be repeated. The equivalent circuit 500 illustrated in FIG. 5C is an equivalent circuit of the driver circuit 100 in FIG. 3B. As illustrated in FIG. 5C, one of the terminals of the inductor 540 in the equivalent circuit 500 corresponding to the driver circuit 100 in FIG. 3B is connected to the current-source equivalent circuit 550, and the other terminal is connected to the input element 510 and the output element 561.

Calculation Results of Impedance in Equivalent Circuit

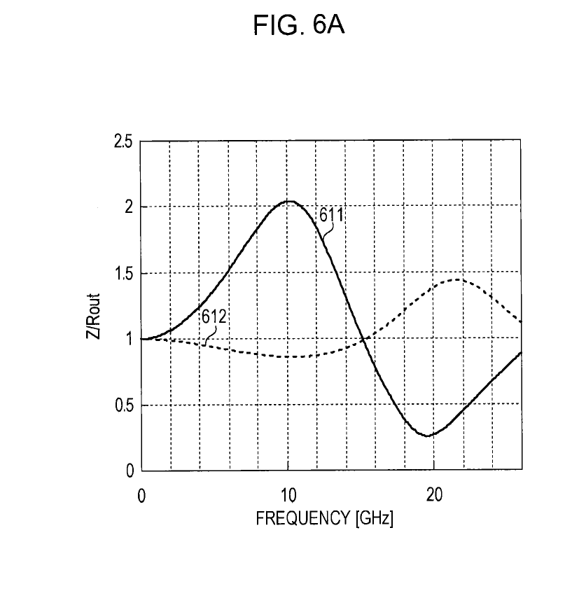

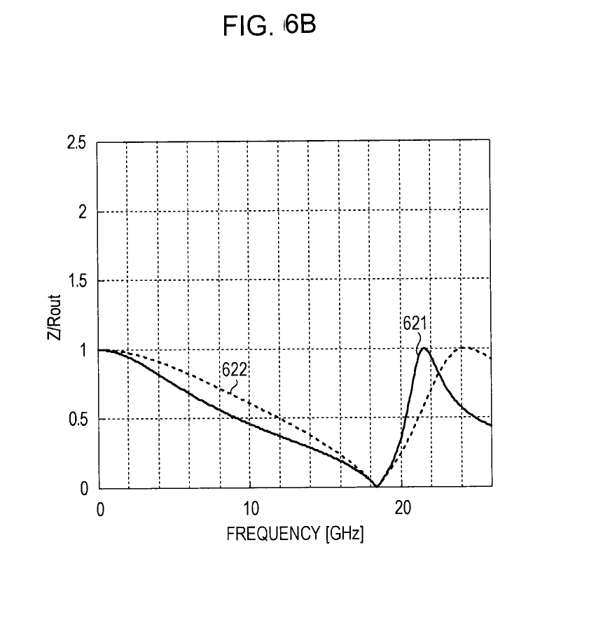

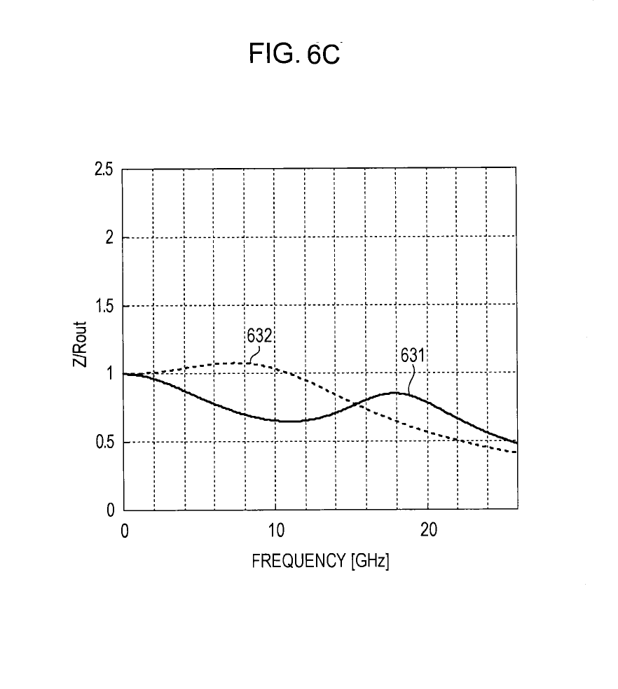

FIG. 6A illustrates exemplary calculation results of the impedance in the equivalent circuit illustrated in FIG. 5A. In FIG. 6A, the transverse axis represents frequency, and the vertical axis represents Z/Rout. The impedance characteristic curve 611 illustrated in FIG. 6A is an exemplary calculation result of Z/Rout of the equivalent circuit 500 in FIG. 5A.

The impedance characteristic curve 612 represents, for reference, an exemplary calculation result of Z/Rout where the current-source equivalent circuit 550 is replaced with a resistor in the equivalent circuit 500 in FIG. 5A (in a case of the CML). The impedance characteristic curve 611 indicates that the parasitic capacitance Cc of the capacitor 552 of the current-source equivalent circuit 550 in the equivalent circuit 500 illustrated in FIG. 5A causes an increase in the maximum value of impedance.

The calculation results in FIG. 6A are obtained through calculations where the capacitance C1 of the capacitor 520 is 200 fF, the capacitance C2 of the capacitor 562 is 150 fF, the capacitance Cc of the capacitor 552 is 200 fF, the resistance Rc of the resistor 553 is 50Ω, the inductance of the inductor 540 is 500 pH, and the Rout is 50Ω. These values are the same for the calculation results in FIGS. 6B and 6C.

FIG. 6B illustrates, for reference, the calculation results of impedance of the equivalent circuit illustrated in FIG. 5B. In FIG. 6B, the transverse axis represents frequency, and the vertical axis represents Z/Rout. The impedance characteristic curve 621 in FIG. 6B represents an exemplary calculation result of Z/Rout of the equivalent circuit 500 in FIG. 5B. The impedance characteristic curve 622 represents, for reference, an exemplary calculation result of Z/Rout where the current-source equivalent circuit 550 of the equivalent circuit 500 in FIG. 5B contains only a resistor (in a case of the CML).

FIG. 6C illustrates, for reference, an exemplary calculation result of impedance in the equivalent circuit illustrated in FIG. 5C. In FIG. 6C, the transverse axis represents frequency, and the vertical axis represents Z/Rout. The impedance characteristic curve 631 in FIG. 6C represents an exemplary calculation result of Z/Rout of the equivalent circuit 500 in FIG. 5C. The impedance characteristic curve 632 represents, for reference, an exemplary calculation result of Z/Rout where the current-source equivalent circuit 550 of the equivalent circuit 500 in FIG. 5C contains only a resistor (in a case of the CML).

The impedance characteristic curves 611, 621, and 631 respectively illustrated in FIGS. 6A, 6B, and 6C indicate that a large peak may be obtained by providing the inductor 140 at the position indicated in FIG. 1, and the frequency band may be widened by controlling the inductance such that the peak corresponds to a desired frequency. The impedance characteristic curves 611 and 612 in FIG. 6A indicates that the configuration in which the inductor 140 is disposed at the position illustrated in FIG. 1 is more efficient in the driver circuit 100 where a current source is connected to the output terminal than in the CML 330.

Modifications of Driver Circuit

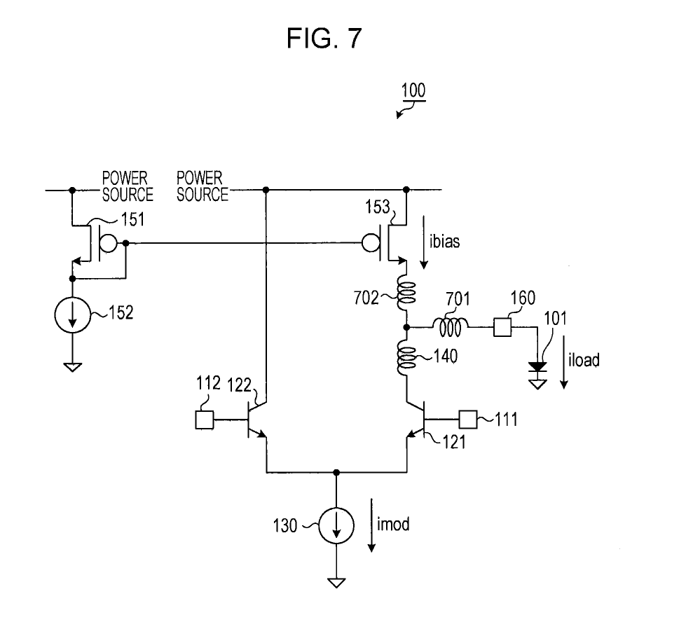

FIG. 7 illustrates a modification 1 of the driver circuit illustrated in FIG. 1. In FIG. 7, the same elements as those illustrated in FIG. 1 will be designated by the same reference numerals, and descriptions thereof will not be repeated. As illustrated in FIG. 7, at least one of inductors 701 and 702 may be disposed between the transistor 153, which is a biased current source, and the output element 160 in the driver circuit 100 in FIG. 1.

The inductors 701 and 702 respectively correspond to the inductor 140 in FIG. 3A and the inductor 140 in FIG. 3B. Specifically, the inductor 701 is a series inductor in which one of the terminals is connected between the transistor 153 (biased current source) and the inductor 140 (series inductor), and the other terminal is connected to the output element 160. The inductor 702 is a shunt inductor in which one of the terminals is connected to the transistor 153 (biased current source), and the other terminal is connected between the inductor 140 (series inductor) and the output element 160.

In this way, by further providing the inductors 701 and 702, a larger peak may be achieved, and the frequency band may be widened even more.

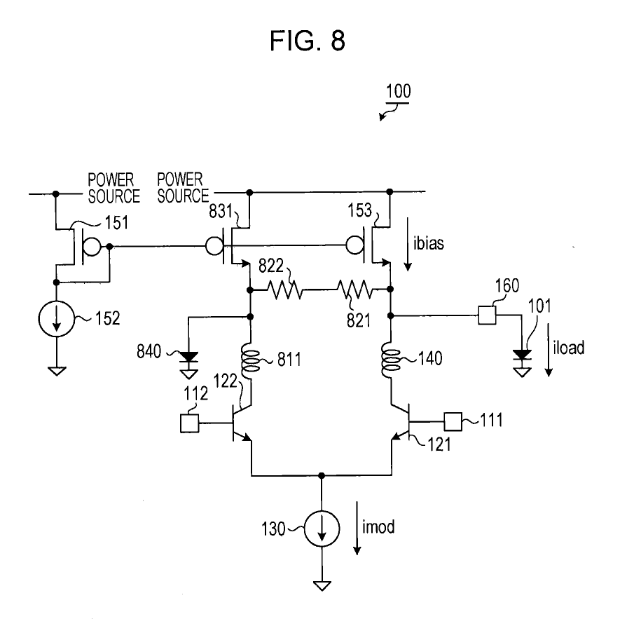

FIG. 8 illustrates a modification 2 of the driver circuit illustrated in FIG. 1. In FIG. 8, the same elements as those illustrated in FIG. 1 will be designated by the same reference numerals, and descriptions thereof will not be repeated. As illustrated in FIG. 8, the driver circuit 100 may include an inductor 811, resistors 821 and 822, a transistor 831, and a terminal resistor 840, in addition to the configuration illustrated in FIG. 1.

One of the terminals of the inductor 811 (second series inductor) is connected to the collector of the input transistor 122 (second input transistor), and the other terminal is connected to the source of the transistor 831. One of the terminals of the resistor 821 is connected to the transistor 153, the inductor 140, and the output element 160, and the other terminal is connected to the resistor 822. One of the terminals of the resistor 822 is connected to the resistor 821, and the other terminal is connected to the inductor 811, the transistor 831, and the terminal resistor 840. The resistors 821 and 822 are each, for example, 50Ω. The resistors 821 and 822 may be achieved using a single resistor (for example, 100Ω).

The source of the transistor 831 (second biased current source) is connected to the inductor 811, the resistor 822 and the terminal resistor 840. The drain of the transistor 831 is connected to the power source. The gate of the transistor 831 is connected to the transistor 151 (current source). The transistor 831 is a pMOS.

The terminal resistor 840 is a dummy load having diode characteristics similar to the characteristics of the light-emitting element 101. The diode characteristics are the characteristics of, for example, the current flowing in response to an applied voltage. One of the terminals of the terminal resistor 840 is connected to the inductor 811, the resistor 822, and the transistor 831, and the other terminal is grounded. In this way, the quality of the drive signal may be improved by matching the impedance of the driver circuit 100 to the impedance of the light-emitting element 101.

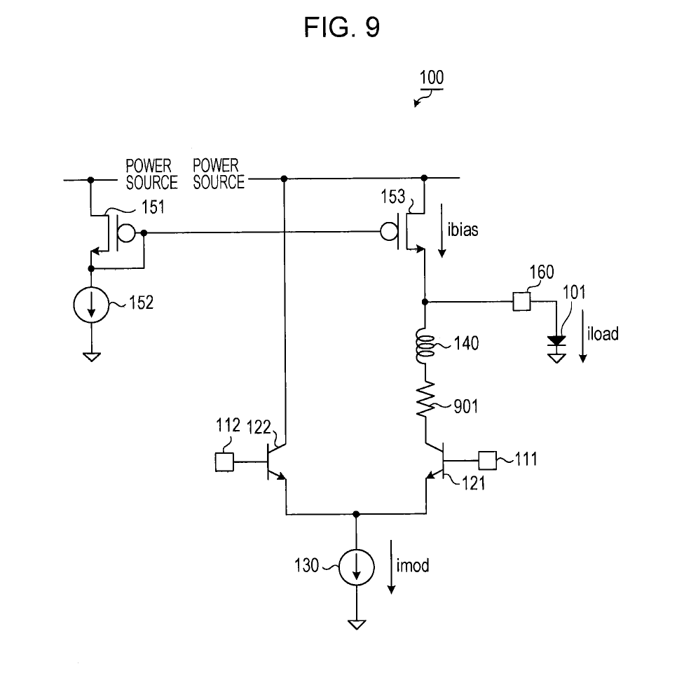

FIG. 9 illustrates a modification 3 of the driver circuit illustrated in FIG. 1. In FIG. 9, the same elements as those illustrated in FIG. 1 will be designated by the same reference numerals, and descriptions thereof will not be repeated. As illustrated in FIG. 9, the driver circuit 100 may include a resistor 901 that is in series with the inductor 140. Specifically, one of the terminals of the resistor 901 is connected to the input transistor 121, and the other terminal is connected to the inductor 140. The positions of the inductor 140 and resistor 901 may be switched.

By providing the resistor 901 in series with the inductor 140, the peak value of the drive signal may be controlled by the inductor 140.

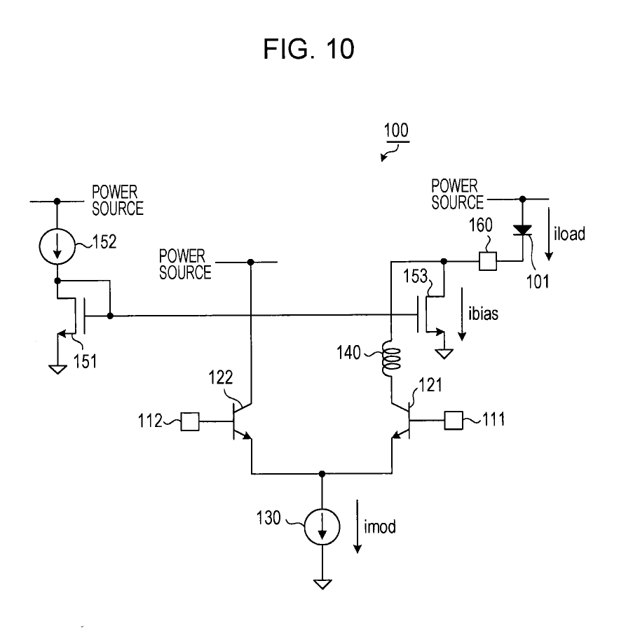

FIG. 10 illustrates a modification 4 of the driver circuit illustrated in FIG. 1. In FIG. 10, the same elements as those illustrated in FIG. 1 will be designated by the same reference numerals, and descriptions thereof will not be repeated. As illustrated in FIG. 10, the driver circuit 100 may perform cathode driving of the light-emitting element 101.

Specifically, in the driver circuit 100 illustrated in FIG. 10, the output element 160 is connected to the cathode of the light-emitting element 101. The transistor 153 (biased current source) is connected reversely. The transistor 153 is an nMOS.

The current source 152 (current source) is connected reversely. The transistor 151 is an nMOS. In this way, in a configuration in which cathode driving is performed on the light-emitting element 101, the inductor 140 may be disposed between the collector of the input transistor 121 and the output element 160 to achieve the advantages similar to those of the driver circuit 100 in FIG. 1.

As illustrated above, in the driver circuit and the optical transmitter, a series inductor is disposed at a predetermined position (for example, see FIG. 1) in the driver circuit in which a current source is connected to the output terminal where a drive signal is modulated and output to the current-driven light-emitting element. Accordingly, reduction in the frequency band due to the capacitance of the current source connected to the output terminal is compensated for, and the frequency band may be widened. Thus, for example, high-speed driving of the light-emitting element in optical interconnect is achieved.

The above-described inductors 140, 701, 702, and 811 may each be constituted of a spiral inductor or a hollow wire. The above-described output elements 160 and 561 may each be constituted of a wiring, a wiring connected to another circuit, a pad and an electric terminal.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment of the present invention has been described in detail, it should be understood that the various changes, substitutions, and alterations could be made hereto without departing from the spirit and scope of the invention.

What is claimed is:

1. An apparatus, comprising:
a first input transistor to include a base receiving a drive signal for an object to be driven;
a first current source connected to an emitter side of the first input transistor and configured to control a modulation amplitude of a signal flowing to a collector of the first input transistor;
a second current source connected to a collector side of the first input transistor and configured to control a biased current of a signal flowing to the collector;
a first inductor configured to dispose between the collector and the second current source; and
an output element connected between the second current source and the first inductor and configured to output, to the object, a current signal of which the modulation amplitude is controlled by the first current source and the biased current is controlled by the second current source.

2. The apparatus according to claim 1, further comprising:
a second inductor including a first terminal connected between the second current source and the first inductor and a second terminal connected to the output element.

3. The apparatus according to claim 1, further comprising:
a third inductor including a first terminal connected to the second current source and a second terminal connected between the first inductor and the output element.

4. The apparatus according to claim 1, further comprising:
a second input transistor including a base receiving a reversed phase signal of the drive signal;
a second current source connected to a collector side of the second input transistor and configured to control a biased current of a signal flowing to the collector of the second input transistor;
a fourth inductor disposed between the collector of the second input transistor and the second current source; and
a terminal resistor connected between the second current source and the fourth inductor and having diode characteristics equivalent to the object to be driven.

5. The apparatus according to claim 1, further comprising:
a resistor disposed in series with the first inductor.

6. The apparatus according to claim 1, wherein the first input transistor includes a heterojunction bipolar transistor (HBT).

7. The apparatus according to claim 1, wherein the first inductor includes a spiral inductor.

8. The apparatus according to claim 1, wherein the first inductor includes a hollow wire.

9. The apparatus according to claim 2, wherein the second inductor includes a spiral inductor.

10. The apparatus according to claim 2, wherein the second inductor includes a hollow wire.

11. The apparatus according to claim 4, wherein the fourth inductor includes a spiral inductor.

12. The apparatus according to claim 4, wherein the fourth inductor includes a hollow wire.

13. The apparatus according to claim 1, further comprising
a light-emitting element connected to the output element.

14. The apparatus according to claim 13, wherein the light-emitting element is a vertical cavity surface emitting laser (VCSEL).

15. An apparatus, comprising:
an input transistor including a gate to which a drive signal of the object to be driven is input;
a first current source connected to a source side of the input transistor and configured to control a modulation amplitude of a signal flowing to a drain of the input transistor;
a second current source connected to a drain side of the input transistor and configured to control a biased current of a signal flowing to the drain;
an inductor disposed between the drain and the second current source; and
an output element connected between the second current source and the inductor and configured to output, to the object to be driven, a current signal whose modulation amplitude is controlled by the first current source and whose biased current is controlled by the second current source.

16. The apparatus according to claim 15, wherein the input transistor is a complementary metal oxide semiconductor (CMOS).

17. The apparatus according to claim 15, further comprising:
a light-emitting element connected to the output element.
